(19) United States
(12) Patent Application Publication
(10) Pub. No.: US 2021/0020712 A1
(43) Pub. Date: Jan. 21, 2021

(54) ORGANIC LIGHT-EMITTING DIODE DISPLAY PANEL AND METHOD OF MANUFACTURING SAME, AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Yue ZHANG, Wuhan, Hubei (CN)

(21) Appl. No.: 16/612,434

(22) PCT Filed: Sep. 19, 2019
(86) PCT No.: PCT/CN2019/106803

§ 371 Date: Nov. 11, 2019

(30) Foreign Application Priority Data
Jul. 18, 2019 (CN) 201910650220.1

(51) Int. Cl. H01L 27/32

(52) U.S. Cl. CPC H01L 27/3246; H01L 27/3211

(57) ABSTRACT

An active matrix organic light-emitting diode panel which can prevent color shift occurring on a periphery of a display region. Red, green, and blue (RGB) pixel units that are arranged randomly at a non-normal pixel structure and a cathode that corresponds to the RGB pixel units are in a floating state. Therefore, when a non-normal pixel structure receives control signals of displaying images, the images that correspond to the control signals can be normally displayed. The problem of color shift is improved.

### FIELD

The present disclosure relates to a field of display technology and, more particularly, relates to an organic light-emitting diode display panel and a method of manufacturing same, and a display device.

### BACKGROUND

Organic light-emitting diode (OLEDs) are an optical technology that realizes multicolor display using a reversible change of color caused by applying current to organic conductive materials. The OLEDs have a variety of advantages such as being light and thin, high brightness, self-luminescence, low power consumption, fast response times, flexibility, wide working temperatures, and so on, and are regarded as the most promising next-generation display technology. An OLED display device includes a substrate, an anode, an organic luminescent layer (including a hole transport layer, a composite luminescent layer, and an electron transport layer.), a cathode, and an encapsulation layer. The OLED display device usually manufactured by sequentially depositing films in a vacuum environment.

The OLED devices can be classified into bottom-emitting OLED devices and top-emitting OLED devices based on a direction that emitted light exits the device. In the bottom-emitting OLED devices, light exits from a side of ITO anode/substrate, while in the top-emitting OLED devices, light exits from a side of a translucent cathode at a top. The bottom-emitting OLED devices are widely used in research institutes due to their relatively simple manufacturing processes. In the top-emitting OLED devices, light exits from the top, so the light will not be blocked by driving circuits. Therefore, the top-emitting OLED devices have a high aperture, high brightness, high efficiency, and long lifetime. Thus, a microcavity effect in the top-emitting OLEDs can change the distribution of coordinate space and frequency space, thereby improving luminous efficiency of monochromatic light of the top-emitting OLED devices, and improving color saturation of the top-emitting OLED devices.

However, only 20% of light can be emitted outside a top-emitting OLED device, the other 80% of light is confined inside the top-emitting OLED device because the light undergoes total internal reflection at a cathode of the top-emitting OLED device. To increase light output rate, an organic capping layer (CPL) with high refractive index is usually deposited on a cathode of the top-emitting OLED device to attenuate the total internal reflection at the cathode. In a blue light-emitting region, the organic CPL has a relatively high refractive index, while in a red light-emitting region and a green light-emitting region, the organic CPL has a relatively low refractive index.

### SUMMARY

One aspect of the present disclosure is to provide an OLED display panel and a method of manufacturing same, and a display device, which can solve a problem of conventional top-emitting OLED devices.

To solve the above problem, one embodiment of the present disclosure provides an OLED display panel, including: a substrate; at least one pixel unit disposed on the substrate; and an organic capping layer (CPL) disposed on the at least one pixel unit. The at least one pixel unit at least includes a first sub-pixel and a second sub-pixel. The organic CPL includes a first CPL and a second CPL. The first CPL is disposed on the at least one pixel unit, the second CPL is disposed on the first CPL, and the second CPL is disposed above the first sub-pixel and the second-pixel.

Furthermore, a thickness of the second CPL is D, a thickness of the first capping is D₂ when the OLED display panel has the highest blue-light outcoupling efficiency, a thickness of the organic CPL is D₃ when the OLED display panel has the highest red-light outcoupling efficiency, and a thickness of the organic CPL is D₄ when the OLED display panel has the highest green-light outcoupling efficiency; and wherein D=D₁−D2, and D₄<D₁<D₃.

Furthermore, the at least one pixel unit further includes a third sub-pixel and a fourth sub-pixel. The third sub-pixel, the fourth sub-pixel, the first sub-pixel, and the second sub-pixel are disposed on a same layer.

Furthermore, an area of the first sub-pixel is less than an area of the fourth sub-pixel.

Furthermore, a pixel arrangement structure of the OLED display panel includes: the second sub-pixel, wherein a center of the second sub-pixel overlaps a center of a virtual square; the first sub-pixel, wherein a center of the first sub-pixel is disposed on a point of a diagonal of the virtual square; the fourth sub-pixel, wherein a center of the fourth sub-pixel is disposed on the other point of the diagonal of the virtual square; and at least two third sub-pixels, wherein centers of the at least two third sub-pixels are respectively disposed on two points of the other diagonal of the virtual square.

Furthermore, material of the organic CPL is a transparent material.

Furthermore, a refractive index of the organic CPL is greater than 1.7.

One embodiment of the present disclosure further provides a method of manufacturing an organic light-emitting diode (OLED) display panel, including: providing a substrate; forming a pixel unit on the substrate; depositing a transparent organic material on the pixel unit to form a first CPL; and depositing a transparent organic material on the first CPL to form a second CPL.

Furthermore, a thickness of the second CPL is D, a thickness of the first capping is D₂ when the OLED display panel has the highest blue-light outcoupling efficiency, a thickness of the organic CPL is D₃ when the OLED display panel has the highest red-light outcoupling efficiency, and a thickness of the organic CPL is D₄ when the OLED display panel has the highest green-light outcoupling efficiency. D=D₁−D₂, and D₄<D₁<D₃.

One embodiment of the present disclosure further provides a display device, including the above display panel.

Regarding the beneficial effects of the present disclosure: by disposing different thicknesses of organic CPLs that correspond to different colors of light, light outcoupling efficiency of red, green, and blue pixels of an active matrix OLED display panel are improved, and white light outcoupling efficiency of the active matrix OLED display panel is further improved.

### DESCRIPTION OF DRAWINGS

FIG. 1 is a schematic structural diagram of an OLED display panel provided by one embodiment of the present disclosure.

FIG. 2 is a schematic structural diagram of a pixel unit provided by one embodiment of the present disclosure.

FIG. 3 is a schematic structural of a pixel arrangement structure provided by one embodiment of the present disclosure.

FIG. 4 is a flowchart showing a method of manufacturing an OLED display panel provided by one embodiment of the present disclosure.

FIG. 5 is a flowchart showing a method of manufacturing a pixel unit provided by one embodiment of the present disclosure.

FIG. 6 is a schematic structural diagram of a display device provided by one embodiment of the present disclosure.

### DETAILED DESCRIPTION

Hereinafter a preferred embodiment of the present disclosure will be described with reference to the accompanying drawings to exemplify the embodiments of the present disclosure can be implemented, which can fully describe the technical contents of the present disclosure to make the technical content of the present disclosure clearer and easy to understand. However, the described embodiments are only some of the embodiments of the present disclosure, but not all of the embodiments. All other embodiments obtained by those skilled in the art based on the embodiments of the present disclosure without creative efforts are within the scope of the present disclosure.

In the description of the present disclosure, it should be understood that terms such as “center,” “longitudinal,” “lateral,” “length,” “width,” “thickness,” “upper,” “lower,” “front,” “rear,” “left,” “right,” “vertical,” “horizontal,” “top,” “bottom,” “inside,” “outside,” “clockwise,” “counter-clockwise” as well as derivative thereof should be construed to refer to the orientation as then described or as shown in the drawings under discussion. These relative terms are for convenience of description, do not require that the present disclosure be constructed or operated in a particular orientation, and shall not be construed as causing limitations to the present disclosure.

In addition, terms such as “first” and “second” are used herein for purposes of description and are not intended to indicate or imply relative importance or significance. Thus, features limited by “first” and “second” are intended to indicate or imply including one or more than one these features. In the description of the present disclosure, “a plurality of” relates to two or more than two, unless otherwise specified.

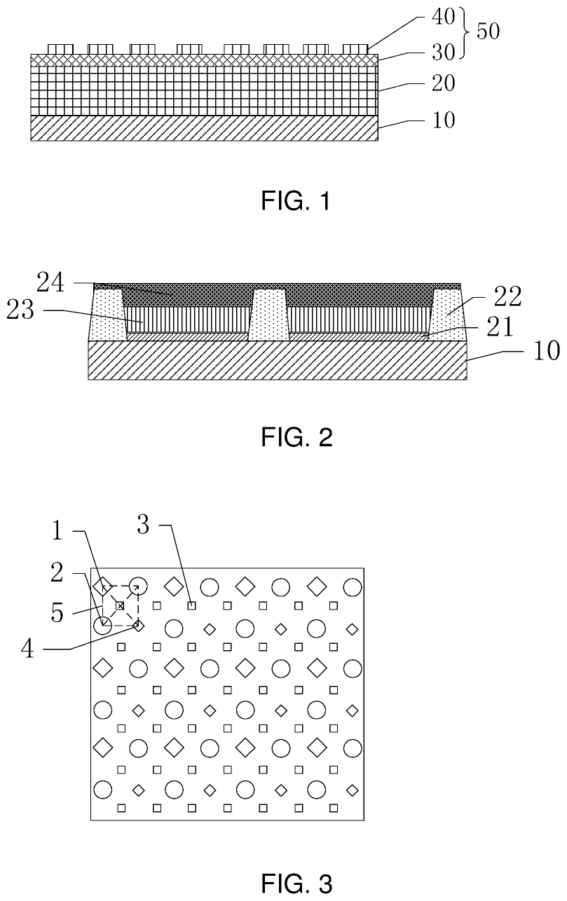

As shown in FIG. 1, FIG. 1 is a schematic structural diagram of an OLED display panel provided by one embodiment of the present disclosure. The OLED display panel includes a substrate 10, a pixel unit 20, and an organic CPL layer 50.

The pixel unit 20 is disposed on the substrate 10, and the organic CPL layer 50 is disposed on the pixel unit 20.

The organic CPL layer 50 includes a first CPL 30 and a second CPL 40. Material of the organic CPL layer 50 is an organic transparent material, a light-cured resin, for example.

Referring to FIG. 3, the pixel unit 20 includes a first sub-pixel 4 and a second sub-pixel 3. The first CPL 30 is disposed on the pixel unit 20, the second CPL 40 is disposed on the first CPL 30, and the second CPL 40 is disposed above the first sub-pixel 4 and the second sub-pixel 3.

In one embodiment of the present disclosure, the second CPL 40 is disposed above the first sub-pixel 4 and the second sub-pixel 3, thereby improving light outcoupling efficiency of the first sub-pixel 4 and the second sub-pixel 3.

In one embodiment of the present disclosure, the first sub-pixel 4 is a red sub-pixel, and the second sub-pixel 3 is a green sub-pixel.

The pixel unit 20 further includes a third sub-pixel 2 and a fourth sub-pixel 1. The third sub-pixel 2 is a blue sub-pixel, and the fourth sub-pixel 1 is a red sub-pixel. An area of the fourth sub-pixel 1 is greater than an area of the first sub-pixel 4.

In one embodiment, a pixel arrangement structure of the OLED display panel includes: the second sub-pixel 3, wherein a center of the second sub-pixel 3 overlaps a center of a virtual square 5; the first sub-pixel 4, wherein a center of the first sub-pixel 4 is disposed on a point of a diagonal of the virtual square 5; the fourth sub-pixel 1, wherein a center of the fourth sub-pixel 1 is disposed on the other point of the diagonal of the virtual square 5; and at least two third sub-pixels 2, wherein centers of the at least two third sub-pixels 2 are respectively disposed on two points of the other diagonal of the virtual square 5.

A thickness of the first CPL layer 30 that corresponds to the fourth sub-pixel 1 (red sub-pixel) is equal to a thickness of the first CPL layer 30 that corresponds to the third sub-pixel 2 (blue sub-pixel). Therefore, loss of light outcoupling efficiency of the fourth sub-pixel 1 (red sub-pixel) caused by the first CPL layer 30 is compensated by enlarging a luminous area of the fourth sub-pixel 1 (red sub-pixel).

Referring to FIG. 2, the pixel unit 20 further includes a pixel defining layer 21, an anode 22, an organic light-emitting layer 23, and a cathode 24. The pixel defining layer 21 and the anode 22 are patterned and formed on the substrate. The organic light-emitting layer 23 is formed on the pixel defining layer 21 and the anode 22. The cathode 24 covers the organic light-emitting layer 24 and the pixel defining layer 21.

A thickness of the second CPL 40 is D, a thickness of the CPL 30 is D₂ when the OLED display panel has the highest blue-light outcoupling efficiency, a thickness of the organic CPL 50 is D₃ when the OLED display panel has the highest red-light outcoupling efficiency, and a thickness of the organic CPL 50 is D₄ when the OLED display panel has the highest green-light outcoupling efficiency. D=D₁−D₂, and D₄<D₁<D₃.

That is, a thickness of the first CPL layer 30 that corresponds the third sub-pixel 2 (blue sub-pixel) is D₂, and a thickness of the first CPL layer 30 that corresponds the fourth sub-pixel 1 (red sub-pixel) is D₂ as well. A luminous area of the fourth sub-pixel 4 is greater than that of the third sub-pixel 2.

In addition, a thickness of the organic CPL 50 (the first CPL 30 and the second CPL 40) that corresponds to the first sub-pixel 4 (red sub-pixel) and the second sub-pixel 3 (green sub-pixel) is D₁, and D₄<D₁<D₃.

In one embodiment of the present disclosure, a thickness of the first CPL layer 30 is D₂, and a thickness of the second CPL 40 is D. Therefore, the third sub-pixel 2 that corresponds to the organic CPL 50 (first CPL 30) reaches maximum light outcoupling efficiency, and light outcoupling efficiency of the first sub-pixel 4 (red sub-pixel) that corresponds to the organic CPL 50 (first CPL 30) and light outcoupling efficiency of the second sub-pixel 3 (green sub-pixel) that corresponds to the organic CPL 50 (second CPL 40) are increased. As a result, light outcoupling efficiency of the entire panel is increased.

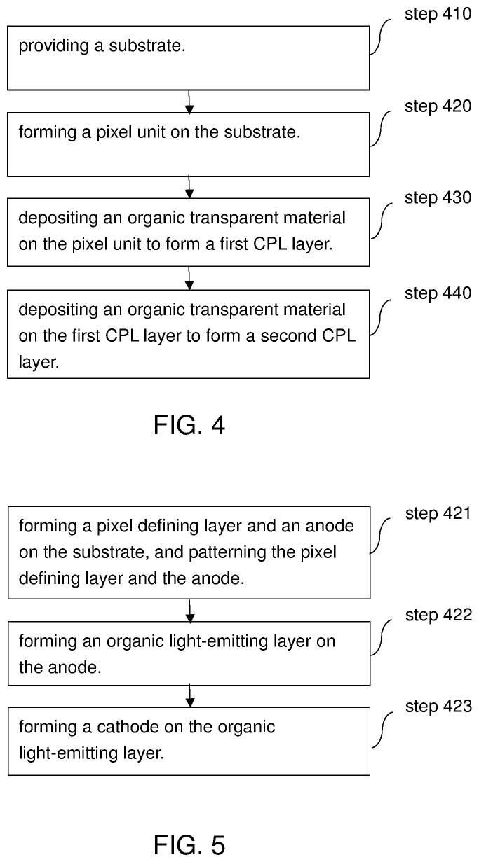

As shown in FIG. 4, the present disclosure further provides a method of manufacturing an OLED display panel, including a plurality of steps of: step 410: providing a substrate 10; and step 420: forming a pixel unit 20 on the substrate.

Referring to FIG. 3, the pixel unit 20 at least includes a first sub-pixel 4 and a second sub-pixel 3.

In one embodiment of the present disclosure, the first sub-pixel 4 is a red sub-pixel, and the second sub-pixel 3 is a green sub-pixel. Of course, in other embodiments, the red sub-pixel, the green sub-pixel, and the blue sub-pixel can be arranged in other ways. For example, the red sub-pixel, the green sub-pixel, and the blue sub-pixel are sequentially arranged side by side.

The pixel unit 20 further includes a third sub-pixel 2 and a fourth sub-pixel 1. The third sub-pixel 2 is a blue sub-pixel, and the fourth sub-pixel 1 is a red sub-pixel. An area of the fourth sub-pixel 1 is greater than an area of the first sub-pixel 4.

Referring to FIG. 5, the step 420: forming a pixel unit 20 on the substrate, further includes the following steps: step 421: forming a pixel defining layer 21 and an anode 22 on the substrate, and patterning the pixel defining layer 21 and the anode 22; step 422: forming an organic light-emitting layer 23 on the anode 22; and step 423: forming a cathode 24 on the organic light-emitting layer 23.

After depositing an anode 42, depositing a first CPL layer 30 with a thickness of D2 on the anode 42 by an open mask. Specific steps are as follows:

step 430: depositing an organic transparent material on the pixel unit 20 to form a first CPL layer 30.

The first CPL 30 is disposed on the pixel unit 20.

step 440: depositing an organic transparent material on the first CPL layer 30 to form a second CPL layer 40.

Changing to another mask and depositing a second CPL layer 40 above the first sub-pixel 4 and the second-pixel 3. A thickness of the second CPL 40 is D, a thickness of the first CPL 30 is D₂ when the OLED display panel has the highest blue-light outcoupling efficiency, a thickness of the organic CPL 50 is D₃ when the OLED display panel has the highest red-light outcoupling efficiency, and a thickness of the organic CPL 50 is D₄ when the OLED display panel has the highest green-light outcoupling efficiency. D=D₁−D₂, and D₄<D₁<D₃.

The first CPL 30 is disposed on the pixel unit 20, the second CPL 40 is disposed on the first CPL 30, and the second CPL 40 is disposed above the first sub-pixel 4 and the second-pixel 3.

The second CPL 40 is disposed above the first sub-pixel 4 and the second-pixel 3, thereby improving light outcoupling efficiency of the first sub-pixel 4 and the second sub-pixel 3.

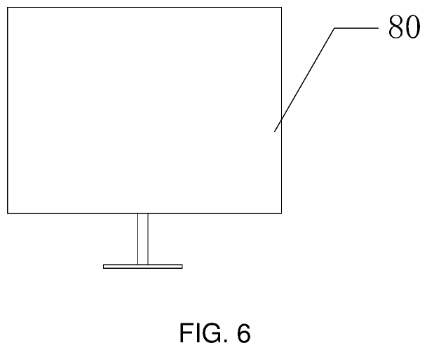

As shown in FIG. 6, one embodiment of the present disclosure further provides a display device 80, including the above display panel.

The display device 80 may be a mobile phone, a tablet, a television, a display, a laptop, a digital frame, a navigator, or any product or component with a display function.

Regarding the beneficial effects of the present disclosure: by disposing different thicknesses of organic CPLs that correspond to different colors of light, light outcoupling efficiency of red, green, and blue pixels of an active matrix OLED display panel are improved, and white light outcoupling efficiency of the active matrix OLED display panel is further improved.

The present disclosure has been described with a preferred embodiment thereof. The preferred embodiment is not intended to limit the present disclosure, and it is understood that many changes and modifications to the described embodiment can be carried out without departing from the scope and the spirit of the disclosure that is intended to be limited only by the appended claims.

1. An organic light-emitting diode (OLED) display panel, comprising
a substrate;
at least one pixel unit disposed on the substrate; and
an organic capping layer (CPL) disposed on the at least one pixel unit;
wherein the at least one pixel unit comprises a first sub-pixel, a second sub-pixel, a third sub-pixel, and a fourth sub-pixel, an area of the first sub-pixel is less than an area of the fourth sub-pixel, and the first sub-pixel and the fourth sub-pixel are red sub-pixels;
wherein the organic CPL comprises a first CPL and a second CPL; and
wherein the first CPL is disposed on the at least one pixel unit, the second CPL is disposed on the first CPL, and the second CPL is disposed above the first sub-pixel and the second sub-pixel.

2. The OLED display panel of claim 1, wherein a thickness of the second CPL is D, a thickness of the first CPL is D2 when the OLED display panel has the highest blue-light outcoupling efficiency, a thickness of the organic CPL is D3 when the OLED display panel has the highest red-light outcoupling efficiency, and a thickness of the organic CPL is D4 when the OLED display panel has the highest green-light outcoupling efficiency; and
wherein D=D1−D2, and D4<D1<D3.

3. The OLED display panel of claim 1,
wherein the third sub-pixel, the fourth sub-pixel, the first sub-pixel, and the second sub-pixel are disposed on the same layer.

4. (canceled)

5. The OLED display panel of claim 3, wherein a pixel arrangement structure of the OLED display panel comprises:
the second sub-pixel, wherein a center of the second sub-pixel overlaps a center of a virtual square;
the first sub-pixel, wherein a center of the first sub-pixel is disposed on a point of a diagonal of the virtual square;
the fourth sub-pixel, wherein a center of the fourth sub-pixel is disposed on the other point of the diagonal of the virtual square; and
at least two third sub-pixels, wherein centers of the at least two third sub-pixels are respectively disposed on two points of the other diagonal of the virtual square.

6. The OLED display panel of claim 1, wherein material of the organic CPL is a transparent material.

7. The OLED display panel of claim 1, wherein a refractive index of the organic CPL is greater than 1.7.

8. A method of manufacturing an organic light-emitting diode (OLED) display panel, comprising:
providing a substrate;
forming a pixel unit on the substrate;
depositing a transparent organic material on the pixel unit to form a first capping layer (CPL); and
depositing a transparent organic material on the first CPL to form a second CPL; and
wherein the pixel unit comprises a first sub-pixel, a second sub-pixel, a third sub-pixel, and a fourth sub-pixel, an area of the first sub-pixel is less than an area of the fourth sub-pixel, and the first sub-pixel and the fourth sub-pixel are red sub-pixels.

9. The method of claim 8, wherein a thickness of the second CPL is D, a thickness of the first CPL is D2 when the OLED display panel has the highest blue-light outcoupling efficiency, a thickness of the organic CPL is D3 when the OLED display panel has the highest red-light outcoupling efficiency, and a thickness of the organic CPL is D4 when the OLED display panel has the highest green-light outcoupling efficiency; and
wherein D=D1−D2, and D4<D1<D3.

10. A display device, comprising the display panel of claim 1.
